(19) United States
(12) Patent Application Publication
(10) Pub. No.: US 2025/0027991 A1
(43) Pub. Date: Jan. 23, 2025

(54) TEST SYSTEM AND TEST METHOD

(71) Applicant: GENERAL TEST SYSTEMS INC., Shenzhen, Guangdong (CN)

(72) Inventors: Wei Yu, Shenzhen, Guangdong (CN); Yihong Qi, Shenzhen, Guangdong (CN)

(21) Appl. No.: 18/714,817

(22) PCT Filed: Oct. 26, 2022
(86) PCT No.: PCT/CN2022/127610

§ 371 Date: May 30, 2024

(30) Foreign Application Priority Data
Dec. 9, 2021 (CN) 202111517330.4

(51) Int. Cl. G01R 31/308; G01R 31/28

(52) U.S. Cl. CPC G01R 31/308; G01R 31/2822

(57) ABSTRACT

Provided are a test system and a test method, which are used for carrying out a wireless test on a device under test to obtain the performance of electromagnetic radiation. The test system comprises a bearing platform, a plurality of test antennas and a motion mechanism, wherein the bearing platform is used for bearing the device under test; the motion mechanism comprises at least two motion units, each motion unit is equipped with the test antenna, and the test antenna is arranged to have a preset angular interval relative to the bearing platform; and a driving unit is used for driving the motion unit, such that the test antenna reaches a plurality of sampling points, the sampling points are located in different angles of the bearing platform, and the angular interval of the sampling points relative to the bearing platform is less than the preset angular interval.

### TECHNICAL FIELD

The present disclosure relates to communication test, and in particular to test systems and test methods for performing wireless test on a device under test to obtain electromagnetic radiation performance.

### BACKGROUND OF THE INVENTION

Test systems for antennas and wireless devices may be classified into single-probe test systems and multi-probe test systems according to the number of test antennas in related art. Such a single-probe test systems may have only one test antenna; and in order to sample at different azimuth and elevation angles of a device under test, one way is to keep the test antenna stationary and control the device under test to rotate in two dimensions. Another way is to control the test antenna to move in the elevation direction of the device under test to coordinate with the one-dimensional rotation of the device under test in the horizontal direction. The multi-probe test system may usually have multiple test antennas fixed around the device under test; and only one-dimensional rotation of the device under test is needed to realize sampling about electromagnetic performance at various angles during testing.

Though the single-probe test system has a simple structure, it requires multiple moves or rotations of the test antenna or the device under test to sample at different spatial positions, resulting in a long test time. The electronic switch of the multi-probe test system can quickly switch between different test antennas to improve test efficiency. However, there may be coupling interference between adjacent test antennas, especially when the sampling resolution is high, the distance between the test antennas is small and the coupling interference is stronger, resulting a decrease in test accuracy.

### SUMMARY OF THE INVENTION

### Technical Problem

The present disclosure mainly provides test systems and test methods for wirelessly testing a device under test, which may be an antenna or a wireless device with an antenna, to obtain electromagnetic radiation performance.

### Solutions of the Problem

### Technical Solutions

According to a first aspect of embodiments of the present disclosure, a test system comprising a bearing platform, a plurality of test antennas and a motion mechanism is provided. The bearing platform may be configured to carry a device under test. The motion mechanism may include at least two motion units, each of which may be equipped with the test antennas, the antennas have a preset angular interval relative to the bearing platform. The motion mechanism may further include a driving unit that may be configured to drive the motion units so that the test antennas reach a plurality of sampling points that are arranged at different angles of the bearing platform and have an angular interval relative to the bearing platform less than the preset angular interval.

According to an embodiment of the test system, the number of the motion units may be equal to the number of the test antennas, and each motion unit may be provided with one test antenna.

According to an embodiment of the test system, it may further include a test instrument configured to sampling when the test antennas reach the sampling points.

According to an embodiment of the test system, the distance between adjacent test antennas may be greater than half of the wavelength corresponding to a test frequency.

According to an embodiment of the test system, the motion mechanism may include a guide rail, and the motion unit may be a slider moved along the guide rail.

According to an embodiment of the test system, the bearing platform may be a one-dimensional rotating platform.

According to an embodiment of the test system, one of the motion units may be equipped with a radio frequency switch connected to all of the test antennas.

According to an embodiment of the test system, each motion unit may be equipped with a radio frequency switch, and each radio frequency switch may be connected with the test antennas in the corresponding motion unit.

According to a second aspect of embodiments of the present disclosure, there is provided a testing method comprising the following steps: arranging a device under test on a bearing platform; dividing a plurality of test antennas into at least two groups and mounting each of the groups thereof on a motion unit, the test antennas being arranged with a preset angular interval with respect to the bearing platform; and driving the motion unit so that the test antennas reach a plurality of sampling points and sampling, the sampling point being arranged at different angles of the bearing platform and having an angular interval relative to the bearing platform less than the preset angular interval of the test antennas.

According to an embodiment of the test method, the distance between adjacent test antennas may be greater than half of the wavelength corresponding to a test frequency.

### BENEFITS OF THE INVENTION

### Benefits

### BRIEF DESCRIPTION OF THE DRAWINGS

### Description of the Drawings

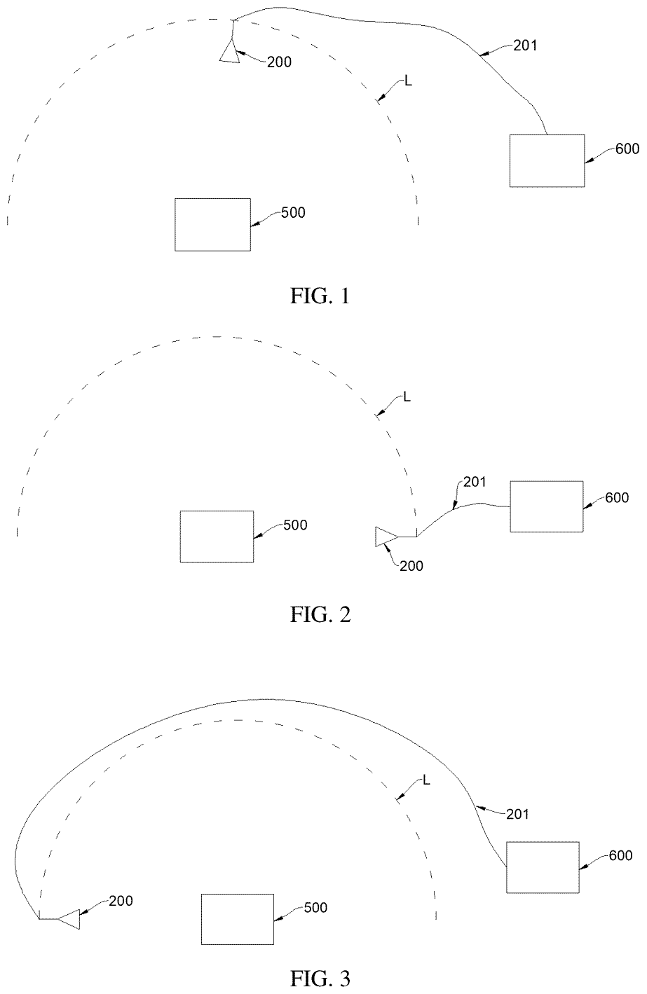

FIGS. 1-3 are schematic diagrams of a single-probe test system in related art;

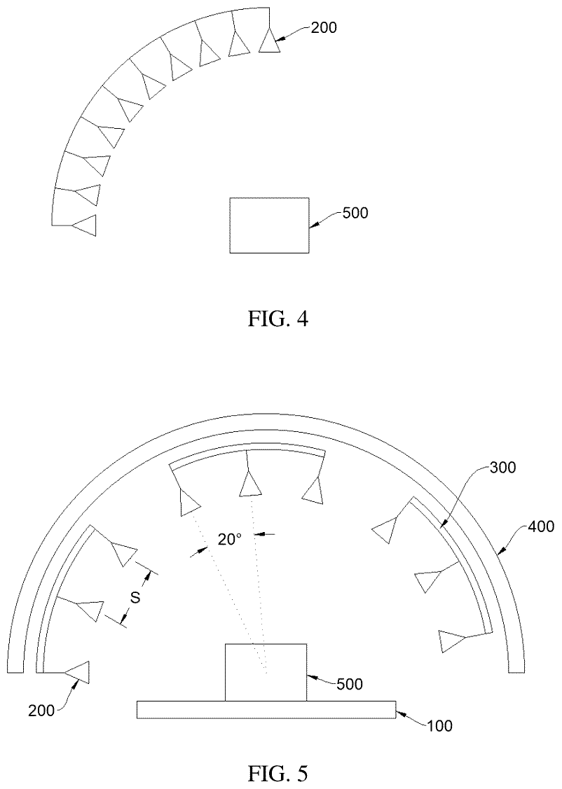

FIG. 4 is a schematic diagram of a multi-probe test system in related art;

FIG. 5 is a schematic diagram of a test system shown according to an embodiment of the present disclosure;

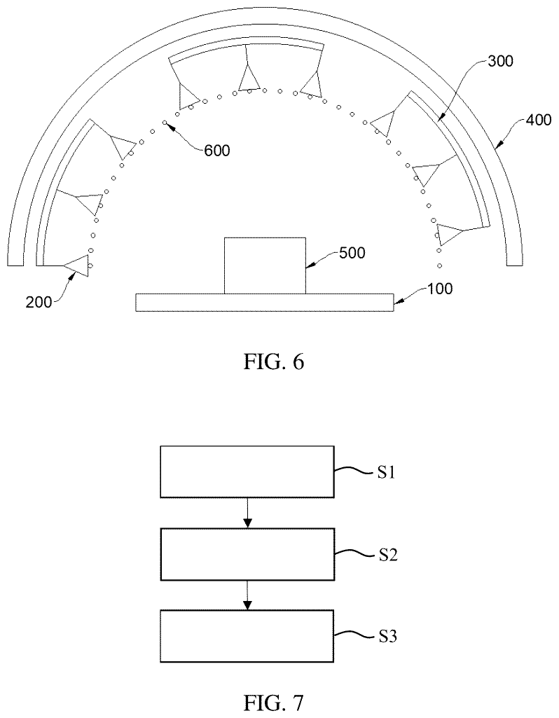

FIG. 6 is a schematic diagram of a test system shown according to an embodiment of the present disclosure; and

FIG. 7 is a flowchart of a test method shown in accordance with an embodiment of the present disclosure.

### DETAILED DESCRIPTION

### Embodiments of the Invention

The embodiments of the present disclosure are described below with reference to the accompanying drawings. It should be understood that the drawings do not have to be of equal proportions. The described embodiments are exemplary, not intended to limit the present disclosure, and can be combined with or substituted for the features of the embodiments in the same or similar manner. The singular forms of “one”, “said” and “the” used in the present disclosure and the appended claims are also intended to include most forms, unless the context clearly indicates other meanings. It should also be understood that the term “and/or” as used herein refers to and includes any or all possible combinations of one or more associated listed items.

Test systems for antennas and wireless devices may be classified into single-probe test systems and multi-probe test systems according to the number of test antennas in related art. The single-probe test system may have only one test antenna; and in order to sample at different azimuth and elevation angles of a device under test, one way is to keep the test antenna stationary and control the device under test to rotate in two dimensions. Another way is to control the test antenna to move in the elevation direction of the device under test to coordinate with the one-dimensional rotation of the device under test in the horizontal direction. The multi-probe test system may usually have multiple test antennas fixed around the device under test; and only one-dimensional rotation of the device under test is needed to realize sampling about electromagnetic performance at various angles during testing. The single-probe test system and the multi-probe test system have their own advantages and disadvantages.

For a large device under test, such as a large antenna, or even a vehicle or an aircraft, it is difficult to rotate in two dimensions. The device under test is usually kept stationary or rotated in the horizontal direction in one dimension in technologies related to wireless test. A single-probe test system in the related technology is shown in FIGS. 1-3 as one embodiment. In the single-probe test system, a test antenna 200 is used to test a device under test 500. The test antenna 200 moves in a circular arc in the elevation direction of the device under test 500. The dotted line L illustrates the motion track of the test antenna 200. When establishing a spherical coordinate system with the center of the device under test 500 as the origin, the angular range of the movement of the test antenna 200 in the elevation direction of the device under test 500 is 180°, and the movement of the test antenna 200 coordinates with the 180° one-dimensional rotation of the device under test 500 in the horizontal direction, realizing the sampling of the upper hemisphere surface of the device under test 500. FIGS. 2-3 illustrate the test antenna 200 locating at two endpoints of its motion track L, respectively. It can be seen that the motion range of the test antenna 200 is very large, which may cause a radio frequency cable 201 connecting the test antenna 200 and a test instrument 600 to repeatedly move and bend in a large range.

When the radio frequency cable is bent, the stability of its phase and amplitude may become worse, thus affecting the test accuracy. In addition, after a period of use, the radio frequency cable failure may occur due to mechanical fatigue. On the other hand, as another embodiment, the multi-probe test system in the related technology is shown in FIG. 4. The multi-probe test system uses multiple test antennas 200 to test the device under test 500. In this embodiment, the multiple test antennas 200 are fixed on an arc-shaped antenna frame centered on the device under test 500, the test antenna 200 is arranged within the range of 0°˜90° in the elevation direction of the device under test 500, and the distribution of the test antenna 200 is consistent with the sampling resolution in the elevation direction of the device under test 500. With the 3600 one-dimensional rotation of device under test 500 in the horizontal direction, the sampling of the upper hemisphere surface of the device under test 500 can be achieved. In such test system, the test antenna is fixed, which avoids repeated bending of the radio frequency cable; however, there is coupling interference between adjacent test antennas, especially for high-resolution sampling, the test antenna distance is small, and the coupling interference is strong, which decrease the test accuracy. Based on the above research findings, a test system and a test method are provided in the present disclosure to overcome the above technical problems to a certain extent.

### Embodiment 1

Referring to FIGS. 5-6, a test system provided in the present disclosure may include a bearing platform 100, nine test antennas 200 and a motion mechanism. Each part thereof is described separately as follows.

The bearing platform 100 may be used to bear the device under test 500.

The motion mechanism may include three motion units 300, each of which may be equipped with three test antennas 200 arranged to have a preset angular interval of 20° with respect to the bearing platform 100.

The motion mechanism may also include a driving unit (not shown in the figure) configured to drive the motion units 300 to move along a preset track so that the test antennas 200 mounted on the motion units 300 reach a plurality of sampling points 600, wherein the sampling points are located at different angles of the bearing platform 100, and the angular interval among the sampling points 600 (relative to the bearing platform 600) is smaller than a preset angular interval (relative to the bearing platform 100) among the test antennas 200. As a specific embodiment, the sampling points 600 shown in FIG. 6 are equidistant, the angular interval between adjacent sampling points 600 relative to the bearing platform 100 is 5°, which is smaller than the preset angular interval 20° of adjacent test antennas 200 relative to the bearing platform 100. It can be seen that in this embodiment, as long as the motion unit 300 moves within 150 of the elevation angle range relative to the bearing platform 100, the test antennas 200 mounted on the motion unit 300 can reach the three sampling points 600 between the adjacent test antennas 200. It can be understood that the three test antennas 200 in a same motion unit 300 are moved synchronously, and the movement of different motion units 300 can be independent of each other or be carried out simultaneously, which can be flexibly set according to test needs. The motion mechanism may achieve the above functions by using a mechanical device in the related technology. In this embodiment, the motion mechanism may include a guide rail 400, the motion unit 300 may be a slider that can move along the guide rail 400, and the drive unit may provide power for the movement of the motion unit 300.

The test system of this embodiment uses multiple sparsely arranged test antennas to reduce coupling and interference caused by test antennas being too close. The sparse arrangement here is relative to the sampling resolution. The movement of the motion unit can theoretically make the test antenna reach any angle between the adjacent test antennas, so as to achieve high-resolution sampling. It can be understood that in this embodiment the multiple test antennas are used to move and sample, and the motion range of the test antennas is necessarily significantly smaller than that of using a single antenna for sampling, which greatly alleviates the problem caused by radio frequency cable bending, and takes into account the test efficiency and test accuracy. In addition, in the test system of this embodiment, the test antennas are mounted on different motion units, making the plurality of test antennas move in groups, which can bring more beneficial effects as follows:
1. providing a plurality of test antennas to different motion units is a good solution for some test scenarios for large devices under test, because: in such scenarios the test antennas may be large and heavy with the sampling range being also large, and, when the plurality of test antennas are moved as a whole, the load will be very heavy, requiring an advanced driving mechanism; and
2. the test system is suitable for more test scenarios by separately controlling the movement of each group of test antennas to allow the movement of at least part of the test antennas to be independent of each other. As an embodiment, only one or more motion units can be used when it is only necessary to test the radiation performance of a partial range of the device under test. As another embodiment, when it is necessary to sample at different resolutions in different areas of a sampling surface, the motion units can be controlled separately to perform different movements and sampling in corresponding areas. As still another embodiment, when testing the MIMO performance of the device under test using the Radiated Two-Stage (RTS) method in prior art, independent movement among the test antennas can help to quickly achieve a transfer matrix with high isolation.

As a special embodiment of the test system according to the present disclosure, the number of the motion unit and the number of the test antennas may be equal, and each motion unit may be provided with one test antenna. Accordingly, each motion unit may be controlled to drive the test antenna to move independently, or all motion units may be controlled to drive the test antennas to move synchronously. This is applicable to test scenarios where the test antenna is larger and heavier, or the sampling range is larger. In addition, the test antennas are more independent and more flexible to use.

The connection among the test antennas and the radio frequency switches may include but be not limited to two optional ways. One way is to install a radio frequency switch on one of the motion units, connect all the test antennas to one end of the radio frequency switch, and connect the other end of the radio frequency switch to the test instrument through a radio frequency cable. The other way is to install a radio frequency switch on each motion unit, connect the test antenna on a motion unit to one end of the radio frequency switch on the same motion unit, and connect the other end of the radio frequency switch to the test instrument through a radio frequency cable.

It can be understood that the preset angular interval of the test antennas relative to the bearing platform herein describes the angular separation between test antennas within one motion unit, because the test antennas in one motion unit have a fixed relative position, while the relative position of the test antennas among the various motion units is not fixed.

The embodiment only provides a specific example. In the present disclosure, the number of the motion units (i.e. the number of the groups of the test antennas) can be determined according to the actual conditions such as sampling accuracy, test items, the number and weight of test antennas, and the driving force of the drive unit; the number of the test antennas arranged in each motion unit can be equal or unequal; and the preset angular interval of the test antennas can be equal or unequal, that is, the test antennas can be equally-spaced or unequally-spaced.

It should be explained that in the present disclosure, when referring to the description of spatial relations with the bearing platform as a reference (such as “the preset angular interval of the test antennas relative to the bearing platform”; “the angle of the sampling points relative to the platform”), the position of the bearing platform should be understood as a point, and more specifically, as the central point of the test. For example, in spherical scanning, the position of the bearing platform can be considered as the center of the spherical scanning, that is, the center of the device under test.

Optionally, the test system may also include a test instrument for sampling when the test antennas reach the sampling points. For example, the test instrument may be at least one of the following in prior art: a vector network analyzer, a vector signal analyzer, a spectrum analyzer, an oscilloscope, and a signal generator.

Optionally, referring to FIG. 5, in order to control the coupling and interference between test antennas 200 to a certain extent, the test antennas 200 can be arranged such that the distance S between adjacent test antennas 200 is greater than half of the wavelength corresponding to the test frequency. Under such distance, the coupling and interference between the test antennas 200 can be controlled to a generally acceptable level. For example, when the test frequency is 600 MHz and the wavelength is 50 cm, the test antenna 200 may need to be arranged so that the distance S between adjacent test antennas 200 is greater than 25 cm.

In this embodiment, the test antenna may be distributed in an arc shape with the bearing platform as the center, and may perform sampling of arc-shaped trajectory on a section in the elevation direction of the device under test. In order to further realize the spherical scanning of the device under test, one way is to control the device under test to rotate in the azimuth direction. Specifically, for example, the bearing platform is a one-dimensional rotating platform for supporting the device under test and driving it to rotate in the horizontal plane; and another way is to move a plurality of test antennas as a whole round the device under test in a horizontal plane. Specifically, for example, the plurality of test antennas are loaded on a movable platform that can move around the device under test.

It should be noted that the present disclosure is not limited to spherical scanning, but also applicable to plane scanning and other scanning methods.

### Embodiment 2

Similar to the above test system, a test method is provided in the present disclosure. Referring to FIG. 7, the test method in this embodiment includes the following steps:
Step S1: arranging a device under test on a bearing platform;
Step S2: dividing a plurality of test antennas into at least two groups and providing each group thereof on a motion unit, the test antennas being arranged to have a preset angular interval with respect to the bearing platform; and Step S3: driving the motion unit so that the test antennas reach a plurality of sampling points and perform sampling, the sampling point being located at different angles of the bearing platform, and the angular interval of the sampling point relative to the bearing platform being smaller than the preset angular interval. Optionally, the distance between adjacent test antennas may be greater than half of the wavelength corresponding to a test frequency.

In the test method of the present disclosure, the implementation sequence of steps S1 and S2 is not limited; such as executing step S2 first and then executing step S1. The explanation of technical details involved in the test method can refer to the above-mentioned description of the test system, and will not be repeated here.

It should be noted that the figures in the present disclosure are simplified schematics, which are only used to schematically illustrate the position relationship and connection relationship among the parts in the embodiments.

In the above description, referring to the description of the terms “one embodiment”, “some embodiments”, “examples”, “specific examples”, or “some examples”, etc., it means that the specific features, structures, materials, or features described in combination with the embodiments or examples are included in at least one embodiment or example of the present disclosure. In the present disclosure, the schematic expression of the above terms does not have to refer to the same embodiment(s) or example(s). Moreover, the specific features, structures, materials or features described may be combined in an appropriate manner in any one or more embodiments or examples.

In addition, the terms “first” and “second” are only used for descriptive purposes and cannot be understood as indicating or implying relative importance or implicitly indicating the number of technical features indicated. Therefore, the features defined as “first” and “second” can explicitly or implicitly include at least one such feature. In the description of the present disclosure, “multiple” or “plurality of” means at least two, such as two, three, etc., unless otherwise specifically defined.

Although the embodiments of the present disclosure have been shown and described above, it can be understood that the above embodiments are exemplary and cannot be understood as restrictions on the present disclosure. Those skilled in the art can change, modify, replace, and transform the above embodiments within the scope of the present disclosure.

1. A test system configured to perform wireless test on a device under test to obtain electromagnetic radiation performance, wherein the test system comprises a bearing platform, a plurality of test antennas and a motion mechanism;
the bearing platform is configured to carry the device under test;
the motion mechanism comprises at least two motion units, each motion unit being equipped with the test antennas, the test antennas have a preset angular interval relative to the bearing platform;
the motion mechanism further comprises a driving unit configured to drive the motion units to allow the test antennas to reach a plurality of sampling points, the sampling points are located at different angles of the bearing platform, an angular interval of the sampling point relative to the bearing platform being less than the preset angular interval;
wherein each motion unit is equipped with at least two test antennas, the at least two test antennas of a same motion unit are moved synchronously, and the movement of different motion units can be independent of each other or be carried out simultaneously.

2. (canceled)

3. The test system according to claim 1, further comprising a test instrument for sampling when the test antennas reach the sampling points.

4. The test system according to claim 1, wherein a distance between adjacent test antennas is greater than half of a wavelength corresponding to a test frequency.

5. The test system according to claim 1, wherein the motion mechanism comprises a guide rail, and the motion unit is a slider that can move along the guide rail.

6. The test system according to claim 1, wherein the bearing platform is a one-dimensional rotating platform.

7. The test system according to claim 1, wherein one of the motion units is equipped with a radio frequency switch which is connected to all of the test antennas.

8. The test system according to claim 1, wherein each of the motion units is equipped with a radio frequency switch which is connected to the test antennas in a corresponding motion unit.

9. A test method for performing wireless test on a device under test to obtain electromagnetic radiation performance, comprising:
arranging the device under test on a bearing platform;
dividing a plurality of test antennas into at least two groups and mounting each group thereof on a motion unit, the test antennas being arranged with a preset angular interval with respect to the bearing platform; and
driving the motion unit to allow the test antennas to reach a plurality of sampling points and sampling, the sampling points being located at different angles of the bearing platform, and an angular interval of the sampling point relative to the bearing platform being less than the preset angular interval;
wherein each motion unit is equipped with at least two test antennas, the at least two test antennas of a same motion unit are moved synchronously, and the movement of different motion units can be independent of each other or be carried out simultaneously.

10. The testing method according to claim 9, wherein a distance between adjacent testing antennas is greater than half of a wavelength corresponding to a test frequency.
